(19) United States
(12) Patent Application Publication
(10) Pub. No.: US 2014/0138854 A1
(43) Pub. Date: May 22, 2014

(54) THERMAL INTERFACE MATERIAL FOR INTEGRATED CIRCUIT PACKAGE ASSEMBLY AND ASSOCIATED TECHNIQUES AND CONFIGURATIONS

(71) Applicant: Hitesh Arora, Chandler, AZ (US)

(72) Inventor: Hitesh Arora, Chandler, AZ (US)

(21) Appl. No.: 13/684,123

(22) Filed: Nov. 21, 2012

(51) Int. Cl. H01L 23/373

(52) U.S. Cl. CPC H01L 23/3737
USPC 257/782; 438/122; 252/74

(57) ABSTRACT

Embodiments of the present disclosure are directed towards a thermal interface material for integrated circuit package assembly and associated techniques and configurations. In one embodiment, an apparatus includes a die and a layer of thermal interface material (TIM) thermally coupled with the die, the TIM including a polymer matrix and carbon filler having anisotropic thermal conductivity disposed in the polymer matrix, the polymer matrix being configured for deposition on the die in liquid form. Other embodiments may be described and/or claimed.

### FIELD

Embodiments of the present disclosure generally relate to the field of integrated circuits, and more particularly, to thermal interface material for integrated circuit package assembly and associated techniques and configurations.

### BACKGROUND

A die may be mounted on a package substrate to form an IC package assembly. A layer of thermal interface material (TIM) may be formed on the die to facilitate heat removal from the die. Current TIM materials may not have sufficient thermal conductivity to meet the thermal resistance requirements for emerging dies or may be costly.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section side view of an example integrated circuit (IC) package assembly including a layer of thermal interface material (TIM), in accordance with some embodiments.

FIG. 2 schematically illustrates an example functional group of the TIM, in accordance with some embodiments.

FIG. 3 schematically illustrates an example TIM deposition technique, in accordance with some embodiments.

FIG. 4 schematically illustrates an example cross-section top view of a nozzle assembly, in accordance with some embodiments.

FIG. 5 schematically illustrates another example TIM deposition technique, in accordance with some embodiments.

FIG. 6 schematically illustrates a cross-section side view of an example integrated circuit (IC) package assembly including multiple dies, in accordance with some embodiments.

FIG. 7 schematically illustrates example thermal pathways for various thicknesses of the layer of TIM, in accordance with some embodiments.

FIG. 8 schematically illustrates a flow diagram for a method of fabricating an IC package assembly, in accordance with some embodiments.

FIG. 9 schematically illustrates a computing device, in accordance with some embodiments.

### DETAILED DESCRIPTION

Embodiments of the present disclosure describe thermal interface material for integrated circuit package assembly and associated techniques and configurations. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature,” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

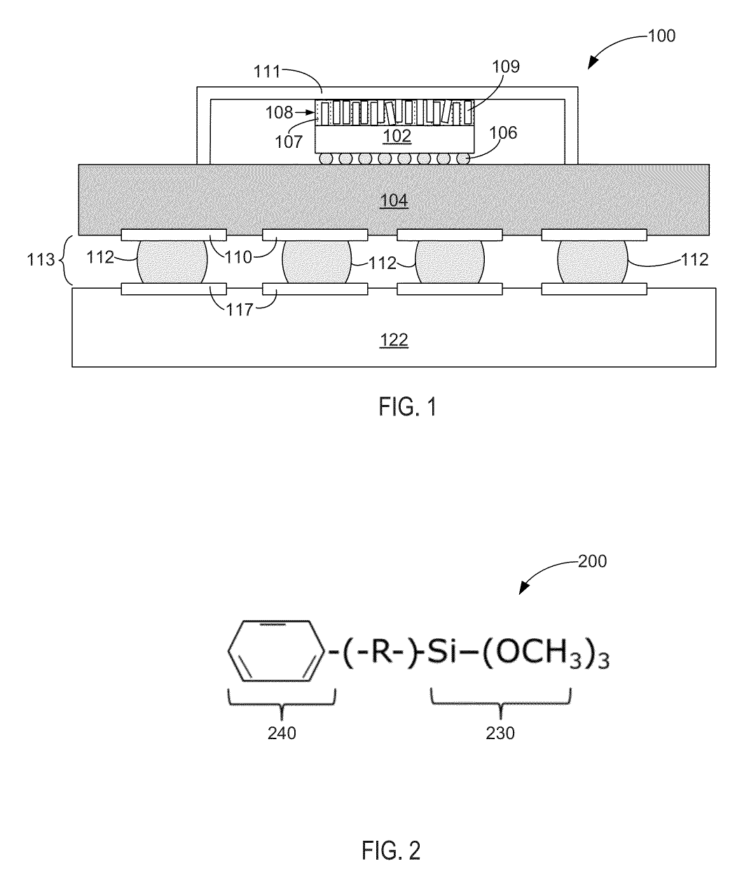

FIG. 1 schematically illustrates a cross-section side view of an example integrated circuit (IC) package assembly 100 including a layer of thermal interface material (hereinafter “TIM 108”), in accordance with some embodiments. The IC package assembly 100 may include a package substrate 104 having one or more dies (hereinafter “die 102”) mounted on the package substrate 104.

The die 102 can be attached to the package substrate 104 according to a variety of suitable configurations including, a flip-chip configuration, as depicted, or other configurations such as wirebonding and the like. In the flip-chip configuration, an active side of the die 102 is attached to a surface of the package substrate 104 using die interconnect structures 106 such as bumps, pillars, or other suitable structures. The active side of the die 102 may have one or more transistor devices formed thereon. The die 102 may represent a discrete chip and may be, include, or be a part of a processor, memory, or ASIC in some embodiments. In some embodiments, an encapsulant (not shown) such as, for example, molding compound or underfill material partially encapsulate the die 102. In some embodiments, the die 102 may be embedded in the package substrate.

The TIM 108 may be thermally coupled with an inactive side of the die 102. According to various embodiments, the TIM 108 may include a thermally conductive material that is configured to route heat away from the die 102 when the die 102 is in operation. The TIM 108 may include, for example, a polymer matrix 107 and carbon filler 109 disposed in the polymer matrix 107. The TIM 108 may include a well-dispersed or randomly-dispersed mixture of material of the polymer matrix 107 and the carbon filler 109.

According to various embodiments, the polymer matrix 107 may be composed of an elastomer. For example, the polymer matrix 107 may be composed of one or more of polystyrene, polybutene, acrylic or silicone rubber. Material of the polymer matrix 107 may be configured for deposition on the die 102 in liquid form (e.g., dispensable). For example, the polymer matrix 107 may have a melting temperature that allows dispense of the TIM 108 on the die 102 using a thermal process to soften the material or otherwise reduce the viscosity of the polymer matrix 107 such that the material can flow through a nozzle of dispense equipment onto the die 102. In some embodiments, the polymer matrix 107 has a melting temperature from 100° C. to 150° C. The polymer matrix 107 may have other melting temperatures in other embodiments.

In other example techniques, a perform technique may be used to deposit a TIM on the die 102. For example, a preform technique may include placement of a preform e.g., pre-cut and pre-cured) material on the die and subsequently heated to provide adhesion between the preform material and the die and heat spreader. However, using a preform for deposition of a TIM on the die 102 may increase stress at interfaces between the die 102 and the TIM 108 and between the TIM 108 and the heat spreader 111 due to assembly process, dynamic and/or static package warpage. A dispensable TIM 108, on the other hand may compensate for such stresses and/or provide a more compressible TIM 108 for IC package assemblies such as, for example, multi-chip packages having height variation between die surfaces.

The carbon filler 109 may be composed of a carbon-based material having anisotropic thermal conductivity. The carbon filler 109 may be configured to conduct more heat in a direction that is parallel with a plane of a crystal lattice of the carbon filler 109 than in a direction that is perpendicular to the plane of the crystal lattice. In some embodiments, the carbon filler 109 may be configured in the form of flakes, nanotubes, sheets, or fibers. In some embodiments, the carbon filler 109 may include non-spherical shapes. The carbon filler 109 may have a thermal conductivity greater than 180 watts per meter degree Kelvin (W/m·K). For example, the thermal conductivity of the carbon filler 109 may be approximately 200 W/m·K in one embodiment. In some embodiments, the carbon filler 109 may be composed of one or more of graphite or grapheme. The carbon filler 109 may include other suitable forms or lattice structures in other embodiments.

According to various embodiments, the TIM 108 may include other materials such as, for example, a crosslinking agent and/or a drag-reducing agent. The crosslinking agent may include, for example, an epoxy or binder. The drag-reducing agent may include long-chain polymers such as, for example, carbon chains having from 10 to 18 carbon atoms in each carbon chain to improve flow of the TIM 108. The crosslinking agent and/or the drag-reducing agent may include other suitable materials in other embodiments.

In some embodiments, prior to cure, the TIM 108 may include from 20 percent by weight (wt %) to 60 wt % of material of the carbon filler 109, from 30 wt % to 40 wt % of material of the polymer matrix 107, from 2 wt % to 10 wt % of a crosslinking agent and/or from 1 wt % to 5 wt % of a drag-reducing agent. The TIM 108 may have a compressibility from 25 microns to 300 microns for application of 10 pounds per square inch (psi) of pressure. The TIM 108 may lose less than 10 wt % (e.g., about 2 wt % to 5 wt %) of total material of the TIM 108 due to volatile solvents in TIM 108 being removed during a cure process. The TIM 108 may include additional suitable materials, other suitable compositions, or other values for compressibility in other embodiments.

In one embodiment, the TIM 108 includes chemical functionality that is configured to form a covalent bond with a surface of the die 102 to increase adhesion. An example functional group 200 of the TIM 108 having such chemical functionality is schematically illustrated in FIG. 2, in accordance with some embodiments.

Referring briefly to both FIG. 1 and FIG. 2, the functional group 200 may include chemical functionality that promotes adhesion of the TIM 108 to the die 102 and/or heat spreader 111. The functional group 200 may include chemical functionality 230 that is configured to form a covalent bond with a surface (e.g., inactive side) of the die 102 and/or a surface of the heat spreader 111. The surfaces of the die 102 and/or the heat spreader 111 may include, for example, an oxide such as, for example, silicon oxide (e.g., SiO₂), nickel oxide, or copper oxide. The functional group 200 may further include chemical functionality 240 that is configured to have chemical affinity to other materials of the TIM 108 such as the polymer matrix 107 and/or the carbon filler 109 by way of T1 electron interactions. The chemical functionality 230 and the chemical functionality 240 may be chemically bonded by one or more carbon atoms (—R—). The functional group 200 may be dissolved in the polymer matrix 107.

Returning again to FIG. 1, the IC package assembly 100 may further include a heat spreader element (hereinafter “heat spreader 111”) such as, for example, an integrated heat spreader (IHS) assembly. The heat spreader 111 may be composed of a thermally conductive material such as, for example, a metal that is thermally coupled with the TIM 108 to route heat away from the die 102 via the TIM 108 when the die 102 is in operation. The heat spreader 111 may be coupled with the package substrate 104 in some embodiments. For example, an adhesive may be used to provide a hermetic seal between the heat spreader 111 and a surface of the package substrate 104. Air may fill a region between the heat spreader 111 and the package substrate 104. In some embodiments, the heat spreader 111 is composed of aluminum, nickel and/or copper. The heat spreader 111 may be composed of a variety of other suitable materials or have other suitable configurations in other embodiments.

In accordance with various embodiments, an IC package assembly 100 in accordance with techniques and configurations described herein may have a junction-to-case thermal resistance (Rjc) as measured through the layer of TIM 108 from the die 102 to the heat spreader 111 that provides adequate cooling for a high performance die such as, for example, a processor. The Rjc may be measured from an active surface of the die to the center of the heat spreader 111.

The die interconnect structures 106 may be configured to route electrical signals between the die 102 and the package substrate 104. In some embodiments, the electrical signals may include, for example, input/output (I/O) signals and/or power or ground signals associated with the operation of the die 102.

The package substrate 104 may include electrical routing features configured to route electrical signals to or from the die 102. The electrical routing features may include, for example, traces (not shown) disposed on one or more surfaces of the package substrate 104 and/or internal routing features such as, for example, trenches, vias or other interconnect structures (not shown) to route electrical signals through the package substrate 104. For example, in some embodiments, the package substrate 104 may include electrical routing features such as die bond pads (not shown) configured to receive the die interconnect structures 106 and route electrical signals between the die 102 and the package substrate 104.

In some embodiments, the package substrate 104 is an epoxy-based laminate substrate having a core and/or build-up layers such as, for example, an Ajinomoto Build-up Film (ABF) substrate. In some embodiments, the package substrate 104 may be configured for back side metallization (BSM), non-BSM, land grid array (LGA), pin grid array (PGA), ball grid array (BGA), high power or lower power configurations. The package substrate 104 may include other suitable types of substrates in other embodiments including, for example, substrates formed from glass, ceramic, or semiconductor materials.

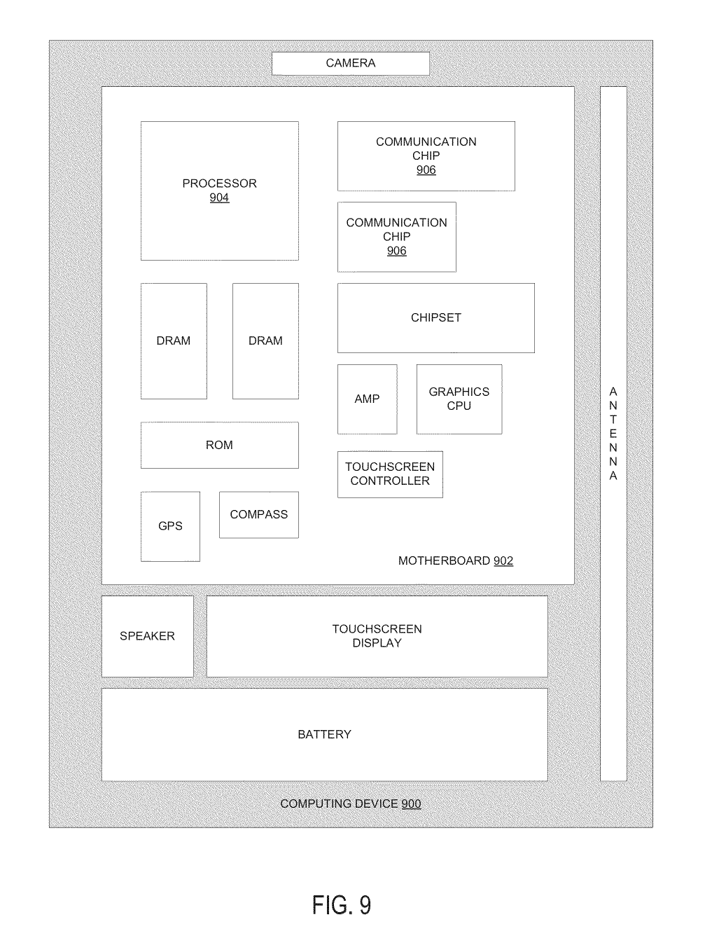

In some embodiments, the circuit board 122 may be a printed circuit board (PCB) composed of an electrically insulative material such as an epoxy laminate. For example, the circuit board 122 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Structures (not shown) such as traces, trenches, vias may be formed through the electrically insulating layers to route the electrical signals of the die 102 through the circuit board 122. The circuit board 122 may be composed of other suitable materials in other embodiments. In some embodiments, the circuit board 122 is a motherboard (e.g., motherboard 902 of FIG. 9).

Package level interconnects 113 including solder material such as, for example, solder balls 112 may be coupled to one or more pads (hereinafter “pads 110”) on the package substrate 104 and/or one or more pads (hereinafter “pads 117”) on the circuit board 122 to form corresponding solder joints that are configured to further route the electrical signals to circuit board 122. The pads 110, 117 may be composed of any suitable electrically conductive material such as metal including, for example, nickel (Ni), palladium (Pd), gold (Au), silver (Ag), copper (Cu), and combinations thereof.

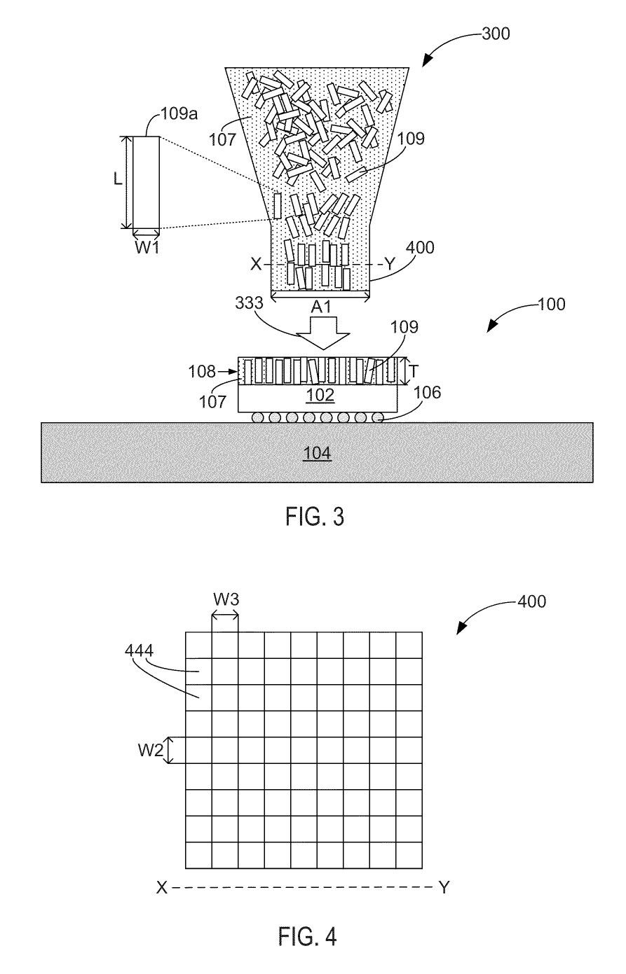

FIG. 3 schematically illustrates an example TIM deposition technique, in accordance with some embodiments. According to a first technique, the TIM 108 may be deposited in a manner that aligns individual particles (e.g., individual particle 109a) of the carbon filler 109 in a common direction to anisotropically conduct heat away from the die 102, as depicted in FIG. 3. The first technique may be advantageous for thermal applications with stringent Rjc requirements.

In some embodiments, a nozzle assembly 300 may include an alignment portion 400 having openings (e.g., openings 444 of FIG. 4) that are configured to align the individual particles of the carbon filler 109 during deposition of the TIM 108 on the die 102 through the nozzle assembly 300. Shear forces of the flow of the TIM 108 through the confined area of the openings may align the individual particles in a common direction (e.g., vertically as shown).

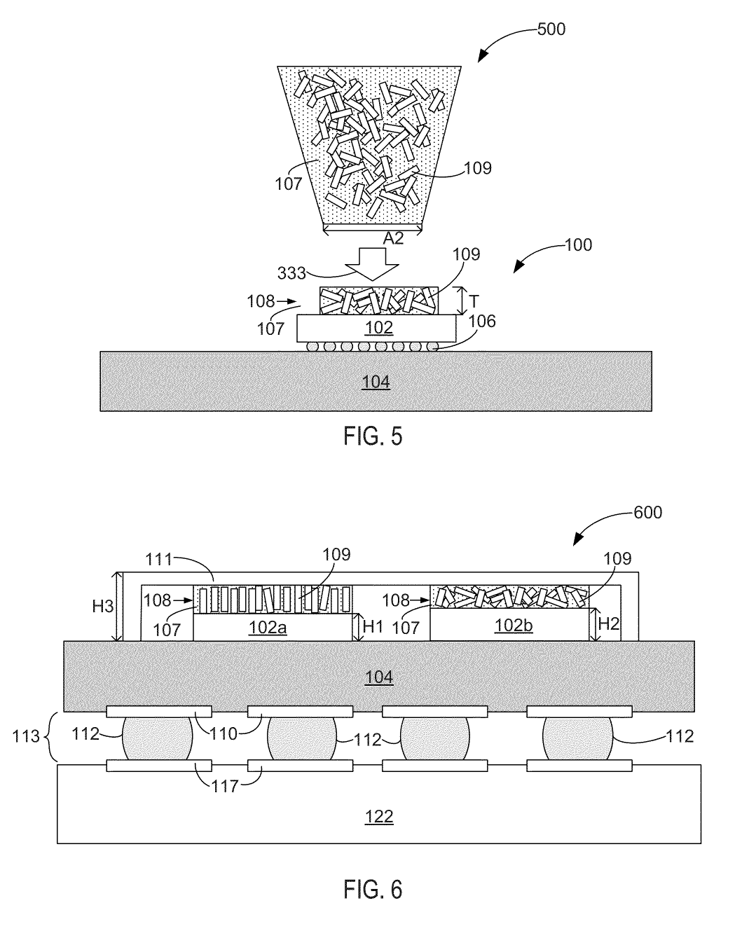

FIG. 4 schematically illustrates an example cross-section top view of a nozzle assembly 300, in accordance with some embodiments. Referring to both FIG. 3 and FIG. 4, the cross-section top view of FIG. 5 may depict a cross-section along line XY through the alignment portion 400 of the nozzle assembly 300 of FIG. 3.

Individual particles (e.g., individual particle 109a) of the carbon filler 109 may have a length, L, and width, W1 that facilitates alignment of the individual particles through alignment portion 400 of the nozzle assembly 300. In some embodiments, thermal conductivity along the length L is greater than thermal conductivity along the width W1. For example, the thermal conductivity along the length L may be about ten times greater than the thermal conductivity along the width W1. An aspect ratio (L:W1) of the individual particles may be greater than or equal to 2:1 in some embodiments. In some embodiments, the aspect ratio of the individual particles may be 10:1 or greater. In some embodiments, the length L may be less than or equal to 100 microns. In some embodiments, the length L may be less than or equal to 50 microns. The carbon filler 109 may have other dimensions in other embodiments.

The alignment portion 400 may have openings 444 with dimensions that facilitate alignment through the alignment portion 400 of the nozzle assembly 300. In some embodiments, the openings 444 may be rectangular having a width, W2, and width, W3, as indicated. The alignment portion 400 may include, for example, a mesh or screen. In some embodiments, the openings 444 may have other profiles including, for example, circular shapes with a diameter that facilitates alignment through the alignment portion 400 of the nozzle assembly 300. A ratio (e.g., W2:W1 or W3:W1) of a width (e.g., W2 or W3) of individual openings of the openings 444 to the width (e.g., W1) of the individual particles may be from 3:1 to 10:1 in some embodiments. The width W2 and/or width W3 may be less than or equal 50 microns in some embodiments.

A dispense area, A1, of the nozzle assembly 300 may correspond with or be the same as a surface area of the die 102 that is configured to receive the TIM 108 to further facilitate alignment of the carbon filler 109 in a direction of the extrusion. Vertical flow of the TIM 108, as indicated by arrow 333, may facilitate vertical alignment of the carbon filler 109 (e.g., as depicted in FIG. 3) and horizontal flow of the TIM 108 may cause horizontal alignment of the carbon filler 109. The dispense area A1 of the nozzle assembly 300 may be smaller than the surface area of the die 102 in some embodiments.

In some embodiments, a thickness, T, sometimes referred to as a bondline thickness (BLT) of the layer of TIM 108 may be defined by the length L of the individual particles of the carbon filler 109. The length L may be used to control the thickness T of the TIM 108. The individual particles (e.g., a substantial majority) of the carbon filler 109 may have a same or similar length L. When deposited by a nozzle assembly 300 that is configured to align the carbon filler 109, a majority of the individual particles of the carbon filler 109 may be aligned in a common direction and provide a thickness T that is defined by the length L of the individual particles. Individual particles of the carbon filler 109 that are not aligned with the common direction may provide horizontal thermal paths to spread heat over the die 102. In other embodiments, the thickness T may be substantially greater than the length L of the carbon filler 109.

FIG. 5 schematically illustrates another example TIM deposition technique, in accordance with some embodiments. According to a second technique, the TIM 108 may be deposited in a manner that does not align individual particles of the carbon filler 109 in a common direction, but rather provides individual particles that are configured in a substantially random orientation in the layer of TIM 108 on the die 102, as depicted in FIG. 5.

The second technique described in connection with FIG. 5 may comport with embodiments of the first technique described in connection with FIG. 3, except that in the second technique the nozzle assembly 500 may not include an alignment portion (e.g., alignment portion 400 of FIGS. 3 and 4) to align the individual particles of the carbon filler 109. In some embodiments, the dispense area, A2, of the nozzle assembly 500 may be smaller than a surface area of the die 102 that is configured to receive the TIM 108. In one embodiment, the dispense area A2 is from 75% to 85% of the surface area of the die 102. According to various embodiments, an amount of TIM 108 is deposited to cover from 75% to 85% of the surface area of the die 102 and placement of the heat spreader element (e.g., heat spreader 111 of FIG. 1) on the deposited TIM 108 may cause the TIM 108 to flow to cover the entire surface area of the die 102 and reduce thickness, T, of the deposited TIM 108. The dispense area, A2, may include a single opening in some embodiments.

A thermal conductivity of the TIM 108 in a vertical direction (e.g., direction parallel with direction indicated by arrow 333) using the second technique may be less than a thermal conductivity of the TIM 108 in the vertical direction using the first technique. However, the second technique may provide a TIM 108 having greater compressibility. Thus, the first technique may provide a higher performance TIM 108 and the second technique may provide a TIM 108 having greater compressibility. Furthermore, a smaller thickness, T, of the layer of TIM 108 may be achieved using the second technique compared with the first technique.

FIG. 6 schematically illustrates a cross-section side view of an example integrated circuit (IC) package assembly 600 including multiple dies (e.g., first die 102a and second die 102b), in accordance with some embodiments. The IC package assembly 600 may comport with embodiments described in connection with FIGS. 1-5 and vice versa. The die interconnect structures 106 are not depicted in FIG. 6, but may be used to couple a first die 102a and second die 102b with the package substrate 104 in various embodiments.

In the depicted embodiment, a first die 102a and second die 102b are mounted on a package substrate 104. The first die 102a may have a height, H1, relative to a surface of the package substrate 104 that is less than a height, H2, of the second die 102b relative to the surface of the package substrate 104. The second die 102b may have a TIM 108 formed thereon in accordance with the second technique described in connection with FIG. 5 and the first die 102a may have a TIM 108 formed thereon in accordance with the first technique described in connection with FIGS. 3-4.

The TIM 108 disposed on the second die 102b may have greater compressibility than the TIM 108 disposed on the first die 102a, allowing a heat spreader 111 of uniform height, H3, to thermally couple with both of the respective layers of TIM 108 disposed on first die 102a and the second die 102b although the respective heights H1 and H2 of the first die 102a and the second die 102b are different. In some embodiments, the first die 102a is a processor and the second die 102b is memory. In other embodiments, the TIM 108 on the first die 102 may be also formed by the second technique. Additional dies may be thermally coupled with the heat spreader 111 using similar principles in various embodiments.

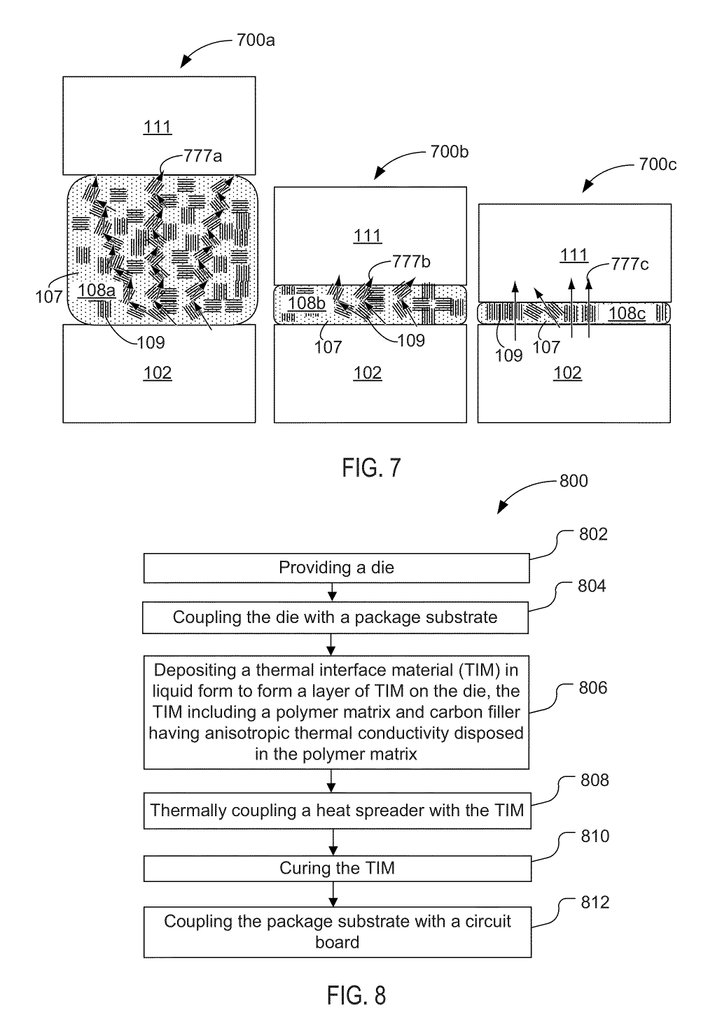

FIG. 7 schematically illustrates example thermal pathways for various thicknesses of the layer of TIM, in accordance with some embodiments. Each of configurations 700a, 700b and 700c includes respective thermal pathways 777a, 777b, 777c through respective TIM 108a, 108b, 108c. The TIM 108a of configuration 700a has a greater thickness than the TIM 108b and the TIM 108c of respective configurations 700b and 700c. The TIM 108b of configuration 700b has a smaller thickness than the TIM 108a of configuration 700a and a greater thickness than the TIM 108c of configuration 700c. The TIM 108c of configuration 700c has a smaller thickness than the TIM 108a and the TIM 108b of respective configurations 700a and 700b.

As can be seen, the smaller thickness of the TIM 108c of configuration 700c provides a more direct thermal pathway 777c from the die 102 to the heat spreader 111 through the carbon filler 109 and may provide faster, more effective or efficient thermal conduction. The larger thickness of the TIM 108b of configuration 700b provides a less direct thermal pathway 777b relative to the thermal pathway 777c and the still larger thickness of the TIM 108a of configuration 700a provides an even less direct thermal pathway 777a from the die 102 to the heat spreader 111 through the carbon filler 109 and may provide slower, less effective or efficient thermal conduction than the TIM 108b and the TIM 108c.

FIG. 8 schematically illustrates a flow diagram for a method 800 of fabricating an IC package assembly (e.g., IC package assembly 100 of FIGS. 1, 3, 5 or IC package assembly 600 of FIG. 6), in accordance with some embodiments. The method 800 may comport with embodiments described in connection with FIGS. 1-8.

At 802, the method 800 may include providing a die (e.g., die 102 of FIG. 1). In some embodiments, providing the die may include fabricating the die. The die may be fabricated, for example, using any suitable semiconductor fabrication processes. In some embodiments, the die may be a processor or memory. In some embodiments, providing the die may include providing multiple dies.

At 804, the method 800 may further include coupling the die with a package substrate (e.g., package substrate 104 of FIG. 1, 3, 5 or 6). In some embodiments, the die may be coupled with the package substrate by mounting the die on the package substrate or embedding the die within the package substrate. In some embodiments, multiple dies are coupled with the package substrate and at least one (e.g., first die 102a of FIG. 6) of the multiple dies may have a height (e.g., height H1) that is different from a height (e.g., height H2) of another (e.g., second die 102b of FIG. 6) of the multiple dies. In some embodiment, providing the die at 802 includes providing the die on the package substrate.

At 806, the method 800 may further include depositing a thermal interface material (TIM) (e.g., TIM 108 of FIG. 1, 3, 5, 6 or 7) in liquid form to form a layer of TIM on the die, the TIM including a polymer matrix (e.g., polymer matrix 107 of FIG. 1, 3, 5, 6 or 7) and carbon filler (e.g., carbon filler 109 of FIG. 1, 3, 5, 6 or 7) having anisotropic thermal conductivity disposed in the polymer matrix. In some embodiments, the TIM may be deposited using the first technique described in connection with FIGS. 3-4. The TIM may be dispensed through a nozzle (e.g., nozzle assembly 300 of FIG. 3) having openings (e.g., openings 444 in alignment portion 400 of FIG. 4) that are configured to align individual particles of the carbon filler in a common direction (e.g., longitudinally vertical as depicted in FIG. 3) to anisotropically conduct heat away from the die.

In other embodiments, the TIM may be deposited using the second technique described in connection with FIG. 5. The TIM may be dispensed through a nozzle (e.g., nozzle assembly 500 of FIG. 5) having an opening (e.g., opening at dispense area A2 of FIG. 5) that is configured to provide a substantially random orientation of individual particles of the carbon filler in the layer of TIM on the die. In the first technique or the second technique, the TIM (e.g., about 5 milligrams (mg) to 10 mg of TIM) may be heated (e.g., to about 50° C.) to reduce viscosity of the TIM such that the TIM can flow through a dispense nozzle.

At 808, the method 800 may further include thermally coupling a heat spreader (e.g., heat spreader 111 of FIG. 1 or 6) with the TIM. According to various embodiments, the heat spreader may be placed or positioned on the TIM for attachment to the TIM by a curing process. In some embodiments, a structure such as, for example, a lid or clip may be positioned to compress (e.g., from 8 psi to 15 psi of pressure) the heat spreader against the TIM and/or the TIM against the die to increase bonding at interfaces between the heat spreader and the TIM and/or between the TIM and the die.

In embodiments where IC package assembly includes multiple dies, the heat spreader may be positioned to compress and spread the TIM disposed on one of the dies (e.g., the second die 102b of FIG. 6) to substantially cover the die and make thermal contact with the TIM disposed on another one of the dies (e.g., the first die 102a of FIG. 6). In this manner, dies having different heights can be accommodated by a heat spreader having a substantially uniform height (e.g., height H3).

At 810, the method 800 may further include curing the TIM. The TIM may be cured by any suitable thermal process including, steady-state or dynamic thermal processes. In one embodiment, the IC package assembly may be subjected to a reflow process to cure and set the TIM. For example, the IC package assembly may be placed in thermal equipment that ramps to a temperature of about 165° C. and holds the temperature for about 10 minutes, followed by a cooling period. In some embodiments, curing the TIM may further increase bonding at interfaces between the heat spreader and the TIM and/or between the TIM and the die. Curing the TIM may set the thickness (e.g., BLT) of the TIM and for sealant that attaches the heat spreader to the package substrate. The sealant may be dispensed on surfaces of the legs of the heat spreader and cured to attach the heat spreader to the package substrate. Curing the TIM may be performed at other suitable temperatures and times in other embodiments.

At 812, the method 800 may further include coupling the package substrate with a circuit board (e.g., circuit board 122 of FIG. 1). The package substrate may be coupled with the circuit board using any suitable technique including, for example, BGA, LGA, or PGA techniques.

Various operations are described as multiple discrete operations in turn, in a manner that is most helpful in understanding the claimed subject matter. However, the order of description should not be construed as to imply that these operations are necessarily order dependent. Embodiments of the present disclosure may be implemented into a system using any suitable hardware and/or software to configure as desired. FIG. 9 schematically illustrates a computing device 900, in accordance with some embodiments. The computing device 900 may house a board such as motherboard 902. The motherboard 902 may include a number of components, including but not limited to a processor 904 and at least one communication chip 906. The processor 904 may be physically and electrically coupled to the motherboard 902. In some implementations, the at least one communication chip 906 may also be physically and electrically coupled to the motherboard 902. In further implementations, the communication chip 906 may be part of the processor 904.

Depending on its applications, computing device 900 may include other components that may or may not be physically and electrically coupled to the motherboard 902. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 906 may enable wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 906 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 906 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 906 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 906 may operate in accordance with other wireless protocols in other embodiments.

The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 may include a die (e.g., die 102 of FIG. 1) in an IC package assembly (e.g., IC package assembly 100 of FIG. 1) as described herein. For example, the circuit board 122 of FIG. 1 may be a motherboard 902 and the processor 904 may be a die 102 mounted on a package substrate 104 of FIG. 1. In some embodiments, the processor 904 may have a layer of TIM (e.g., TIM 108 of FIG. 1), as described herein, thermally coupled with the processor 904 and a heat spreader (e.g., heat spreader 111 of FIG. 1) thermally coupled with the TIM. The term “processor” may refer to any device or portion of a device that processes electronic data from registers and/or memory to transform that electronic data into other electronic data that may be stored in registers and/or memory.

The communication chip 906 may also include a die (e.g., die 102 of FIG. 1) in an IC package assembly (e.g., IC package assembly 100 including TIM 108 of FIG. 1) as described herein. In further implementations, another component (e.g., memory device or other integrated circuit device) housed within the computing device 900 may contain a die (e.g., die 102 of FIG. 1) in an IC package assembly (e.g., IC package assembly 100 including TIM 108 of FIG. 1) as described herein.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus including:
a die; and
a layer of thermal interface material (TIM) thermally coupled with the die, the TIM including a polymer matrix and carbon filler having anisotropic thermal conductivity disposed in the polymer matrix, the polymer matrix being configured for deposition on the die in liquid form.

2. The apparatus of claim 1, wherein:
individual particles of the carbon filler have a length L and a width W; and
an aspect ratio (L:W) of the individual particles is greater than 2:1.

3. The apparatus of claim 2, wherein thermal conductivity of the individual particles along the length L is greater than thermal conductivity of the individual particles along the width W.

4. The apparatus of claim 2, wherein the length L is less than or equal to 100 microns

5. The apparatus of claim 2, wherein the layer of TIM has a thickness that is defined by the length L of the individual particles.

6. The apparatus of claim 2, wherein a majority of the individual particles of the carbon filler are aligned in a common direction to anisotropically conduct heat away from the die.

7. The apparatus of claim 2, wherein the individual particles of the carbon filler are configured in a substantially random orientation in the layer of TIM.

8. The apparatus of claim 1, wherein individual particles of the carbon filler are configured in flakes, nanotubes, sheets, or fibers.

9. The apparatus of claim 1, wherein the carbon filler includes graphite or grapheme.

10. The apparatus of claim 1, wherein the TIM includes from 20 percent by weight (wt %) to 60 wt % of material of the carbon filler and from 30 wt % to 40 wt % of material of the polymer matrix.

11. The apparatus of claim 10, wherein the TIM further includes:
from 2 wt % to 10 wt % of a crosslinking agent;
from 1 wt % to 5 wt % of drag-reducing agent having carbon chains with 10 carbon atoms to 18 carbon atoms in each carbon chain; and
chemical functionality that is configured to form a covalent bond with a surface of the die.

12. The apparatus of claim 1, wherein the layer of TIM, prior to being cured, has a compressibility from 25 microns to 300 microns for 10 pounds per square inch (psi) of pressure.

13. The apparatus of claim 1, wherein the polymer matrix includes an elastomer including one or more of polystyrene, polybutene, acrylic or silicone rubber.

14. The apparatus of claim 1, further comprising:
a heat spreader element thermally coupled with the layer of TIM.

15. The apparatus of claim 14, further comprising:
a package substrate, wherein the die is a first die coupled to the package substrate and the layer of TIM is configured to substantially cover an inactive surface of the first die; and
a second die coupled to the package substrate and having a layer of the TIM disposed on the second die, the first die having a height relative to a surface of the package substrate that is different than a height of the second die relative to the surface of the package substrate, wherein the heat spreader element is thermally coupled with the respective layers of TIM on the first die and the second die.

16. A thermal interface material (TIM) for conduction of heat away from a die, the TIM comprising:
a polymer matrix; and
carbon filler having anisotropic thermal conductivity disposed in the polymer matrix, wherein the polymer matrix is configured for deposition in liquid form.

17. The TIM of claim 16, wherein:
individual particles of the carbon filler have a length L and a width W; and
an aspect ratio (L:W) of the individual particles is greater than 2:1.

18. The TIM of claim 17, wherein thermal conductivity of the individual particles along the length L is greater than thermal conductivity of the individual particles along the width W.

19. The TIM of claim 17, wherein the length L is less than or equal to 100 microns.

20. The TIM of claim 16, wherein the carbon filler includes graphite or grapheme particles configured in flakes, nanotubes, sheets, or fibers.

21. The TIM of claim 16, wherein the TIM includes from 20 percent by weight (wt %) to 60 wt % of material of the carbon filler and from 30 wt % to 40 wt % of material of the polymer matrix.

22. The TIM of claim 21, further comprising:
a crosslinking agent that is from 2 wt % to 10 wt % of the TIM; and
a drag-reducing agent that is from 1 wt % to 5 wt % of the TIM, the drag-reducing agent having carbon chains with 10 carbon atoms to 18 carbon atoms in each carbon chain.

23. The TIM of claim 16, wherein the TIM has a compressibility from 25 microns to 300 microns for 10 pounds per square inch (psi) of pressure subsequent to deposition and prior to being cured.

24. The TIM of claim 16, wherein the polymer matrix includes an elastomer including one or more of polystyrene, polybutene, acrylic or silicone rubber.

25. A method comprising:
providing a die; and
depositing a thermal interface material (TIM) in liquid form to form a layer of TIM on the die, wherein the TIM includes a polymer matrix and carbon filler having anisotropic thermal conductivity disposed in the polymer matrix.

26. The method of claim 25, wherein depositing the TIM comprises dispensing the TIM through a nozzle having openings that are configured to align individual particles of the carbon filler in a common direction to anisotropically conduct heat away from the die.

27. The method of claim 26, wherein:
the individual particles of the carbon filler have a length L and a width W1; and
an aspect ratio (L:W1) of the individual particles is greater than 2:1;
a ratio (W2:W1) of a width W2 of individual openings of the nozzle to the width W1 of the individual particles is from 3:1 to 10:1; and
the length L is less than or equal to 100 microns.

28. The method of claim 25, wherein depositing the TIM comprises dispensing the TIM through a nozzle having an opening that is configured to provide a substantially random orientation of individual particles of the carbon filler in the layer of TIM on the die.

29. The method of claim 25, further comprising:
mounting the die on a package substrate, wherein providing the die comprises providing the die on the package substrate.

30. The method of claim 29, further comprising:
thermally coupling a heat spreader element with the TIM; and
curing the TIM.
